(19) United States
(12) Patent Application Publication
(10) Pub. No.: US 2026/0299883 A1
(43) Pub. Date: Oct. 1, 2026

(54) CONTROL METHOD AND APPARATUS FOR NON-VOLATILE MAJORITY GATE CIRCUIT AND ADDER CIRCUIT BASED ON MEMRISTORS

(71) Applicant: HUAZHONG UNIVERSITY OF SCIENCE AND TECHNOLOGY, Hubei (CN)

(72) Inventors: Xingsheng Wang, Hubei (CN); Zhouchao Gan, Hubei (CN); Yifeng Xiong, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/393,532

(22) Filed: Nov. 18, 2025

(30) Foreign Application Priority Data
Mar. 26, 2025 (CN) 202510361374.4

(51) Int. Cl. G06F 7/503; G11C 13/00

(52) U.S. Cl. CPC G06F 7/503; G11C 13/0023

(57) ABSTRACT

A control method and apparatus for a non-volatile majority gate circuit and an adder circuit based on memristors belonging to the technical field of microelectronic logic operations are provided. In the majority gate circuit, three memristors correspond to input logic values a, b, and c to be subjected to a majority gate logic operation, and a result of the logic operation is determined by a voltage comparator according to a comparison result between a common node voltage and a reference voltage. By changing a voltage of a positive terminal of each memristor, two types of majority gate logic M(a, b, c) and M(a, b, c̅) may be implemented.

### CROSS-REFERENCE TO RELATED APPLICATION

This application claims the priority benefit of China application serial no. 202510361374.4, filed on Mar. 26, 2025. The entirety of the above-mentioned patent application is hereby incorporated by reference herein and made a part of this specification.

### BACKGROUND

### Technical Field

The disclosure belongs to the technical field of microelectronic logic operations, and more specifically, relates to a control method and apparatus for a non-volatile majority gate circuit and an adder circuit based on memristors.

### Description of Related Art

In a conventional computer, the von Neumann architecture is adopted, in which the storage unit and the processing unit are physically separated. Typically, the processing unit reads data from the storage unit, completes the corresponding arithmetic logic operations, and then writes the data back to the storage unit. Frequent read and write operations impose a significant burden on the bus, especially under conditions of limited transmission speed, which not only affects data transmission efficiency but also causes considerable power consumption. Meanwhile, there is a speed mismatch between the processing unit and the storage unit, and this difference is intensifying year by year. Therefore, how to solve the “bottleneck problem” and the “memory wall” problem found in the von Neumann architecture has become a research focus in the field of computer architecture.

To break through these bottlenecks, the computing-in-memory technology has emerged. This technology achieves advantages such as high computational parallelism, low latency, and low power consumption by integrating the computing and storage functions on the same hardware platform, and has gradually become a research hotspot in the academia and industry. As a new type of non-volatile memory devices, memristors have advantages such as low power consumption, small size, and compatibility with CMOS processes, making them ideal candidate devices for in-memory computing architectures. Memristors may store information by changing their resistance states and may maintain their resistance states even after power-off, making them naturally suitable for digital logic operations. By simultaneously selecting multiple memristor units for read operations, specified logic operations or complex arithmetic functions may be completed without explicitly extracting the stored data from the memristors, so that computing-in-memory is achieved. This approach greatly improves the speed and efficiency of information processing.

The majority-inverter graph (MIG) logic is a new type of data logic representation structure composed of the majority (MAJ) gate logic and the inverter (INV) logic, where the logic expression of the three-input majority gate is: M(a, b, c)=a·b+a·c+b·c, and the expression of the inverter logic is: INV(a)=ā. The MAJ and the inverter logic constitute a complete logic set, that is, all Boolean logic functions may be implemented through the iterative MAJ and the inverter logic. Logic optimization includes manipulating logic representation structures to minimize certain target metrics. The logic optimization methods are closely connected to the data structures on which they run, and the MIG logic primitives themselves demonstrate efficient logic synthesis potential. The MIG requires smaller logic depth most of the time to implement the same complex logic and therefore provides improved experimental results in propagation delay. The key point and difficulty in implementing the MIG logic lies in implementing the majority gate logic. The majority gate logic plays a core role in arithmetic circuits such as adders and multipliers as well as complex reasoning tasks. Therefore, it is of great significance to study a majority gate logic circuit.

However, the existing CMOS-based majority gate implementations not only have high hardware complexity, but also have significant delay and power consumption bottlenecks. Implementing the majority gate logic based on memristors provides a new solution to this problem. The existing memristor-based majority gate logic implementation schemes achieve the three-input majority gate logic M(a, b, c)=a·b+a·c+b·c by operating on a, b, and c through three memristor units. Although hardware complexity may be accordingly reduced, this logic scheme only supports single logic operations and lacks implementation of the inverter logic. In multifunctional logic implemented based on the majority gate logic, not only the conventional majority gate logic M(a, b, c)=a·b+a·c+b·c is involved most of the time, but also the majority gate logic with the inverter logic M(a, b, c̅)=a·b+a·c+b·c is involved. Since two different types of the majority gate logic are involved at the same time, if the existing memristor-based majority gate logic implementation schemes are adopted, the majority gate logic M(a, b, c̅) often needs to be decomposed into two independent logic operations: majority gate logic M(a, b, c) and inverter logic, and at least four memristor units are required to operate on a, b, c, and c̅. Therefore, the required number of devices is large, the integration level is low, and the computing speed is low as well, making it unable to satisfy the demand for multifunctional logic in practical applications with high integration level and computing speed.

### SUMMARY

In view of the above defects or improvement needs of the related art, the disclosure provides a control method and apparatus for a non-volatile majority gate circuit and an adder circuit based on memristors configured to solve the technical problem that it is difficult to satisfy the demand for multifunctional logic in practical applications with high integration level and computing speed due to only supporting only a single logic operation in the related art.

To achieve the above, in the first aspect, the disclosure provides a control method for a non-volatile majority gate circuit based on memristors.

The majority gate circuit includes a voltage comparator, a resistor, and three identical memristors. Negative terminals of the three memristors are all connected to one end of the resistor, and the other end of the resistor is grounded. A first input terminal of the voltage comparator is connected to a common node of the three memristors and the resistor, and a resistance value of the resistor is a low resistance state resistance value of the memristors.

The control method includes the following steps.

Logic values a, b, and c to be subjected to a majority gate logic operation are correspondingly written into the three memristors, a voltage Vₐ is applied to a positive terminal of the memristor into which the logic value a is written, a voltage V_{b} is applied to a positive terminal of the memristor into which the logic value b is written, a voltage V_{c} is applied to a positive terminal of the memristor into which the logic value c is written. A reference voltage V_{Ref} is connected to a second input terminal of the voltage comparator. A result of the majority gate logic operation is obtained at an output terminal of the voltage comparator.

When a majority gate logic operation M(a, b, c)=a·b+a·c+b·c is performed on the logic values a, b, and c, Vₐ=V_{b}=V_{c}=V₁, V_{Ref}=V_{Ref1}, 0<V₁<Vₛₑₜ, and V₁/2<V_{Ref1}<2V₁/3.

When a majority gate logic operation M(a, b, c̅)=a·b+a·c̅+b·c̅ is performed on the logic values a, b, and c, Vₐ=V_{b}=V₂, V_{c}=0, V_{Ref}=V_{Ref2}, 0<V₂<Vₛₑₜ, and V₂/3<V_{Ref2}<V₂/2.

Vₛₑₜ is a threshold for each memristor to transition from a high resistance state to a low resistance state. When a voltage at the first input terminal of the voltage comparator is greater than a voltage at the second input terminal, the output terminal outputs a first level, and the first level is used as a result “1” of the majority gate logic operation, otherwise, the output terminal outputs a second level, and the second level is used as a result “0” of the majority gate logic operation.

Further preferably, corresponding logic values are written by setting the high and low resistance states of the memristors. The high resistance state of the memristors corresponds to the logic value “0”, and the low resistance state corresponds to the logic value “1”.

In the second aspect, the disclosure provides a majority gate operation apparatus including a majority gate circuit and a controller.

The majority gate circuit includes a voltage comparator, a resistor, and three identical memristors. Negative terminals of the three memristors are all connected to one end of the resistor, and the other end of the resistor is grounded. A first input terminal of the voltage comparator is connected to a common node of the three memristors and the resistor, and a resistance value of the resistor is a low resistance state resistance value of the memristors.

The controller is configured to execute the control method provided by the first aspect of the disclosure.

In the third aspect, the disclosure provides a control method for an adder circuit used to implement an addition operation of n-bit numbers aₙ . . . a₂a₁ and bₙ . . . b₂b₁. The adder circuit includes a voltage comparator, a resistor, and five memristors. Negative terminals of the five memristors are all connected to one end of the resistor, and the other end of the resistor is grounded. A first input terminal of the voltage comparator is connected to a common node of the five memristors and the resistor, a resistance value of the resistor is a low resistance state resistance value of the memristors, and n≥1.

The control method includes the following. n rounds of addition sub-processes are executed, where in an i^{th} round addition sub-process, the following operations are executed.

Three memristors are selected and denoted as a first memristor, a second memristor, and a third memristor. A logic value aᵢ is written into the first memristor, a logic value bᵢ is written into the second memristor, and a carry cᵢ of the i^{th} round of addition is written into the third memristor.

A voltage V₁ is applied to positive terminals of the first memristor, the second memristor, and the third memristor. A reference voltage V_{Ref1} is connected to a second input terminal of the voltage comparator. A result of a majority gate logic operation M(aᵢ, bᵢ, cᵢ)=aᵢ·bᵢ+aᵢ·cᵢ+bᵢ·cᵢ is obtained at an output terminal of the voltage comparator as a carry cᵢ₊₁ of an (i+1)^{th} round addition.

A voltage V₂ is applied to the positive terminals of the first memristor and the second memristor, and a voltage with an amplitude of 0 is applied to the positive terminal of the third memristor. A reference voltage V_{Ref2} is connected to the second input terminal of the voltage comparator. A result of a majority gate logic operation M(aᵢ, bᵢ, c̅ᵢ)=aᵢ·bᵢ+aᵢ·c̅ᵢ+bᵢ·c̅ᵢ is obtained at the output terminal of the voltage comparator.

The remaining two unset memristors are denoted as a fourth memristor and a fifth memristor. M(aᵢ, bᵢ, cᵢ) is written into the fourth memristor, and M(aᵢ, bᵢ, c̅ᵢ) is written into the fifth memristor.

The voltage V₂ is applied to positive terminals of the third memristor and the fifth memristor, and a voltage with an amplitude of 0 is applied to a positive terminal of the fourth memristor. The reference voltage V_{Ref2} is connected to the second input terminal of the voltage comparator. A result of a majority gate logic operation M(cᵢ, M(aᵢ, bᵢ, c̅ᵢ), M̅(̅a̅ᵢ̅,̅ b̅ᵢ̅,̅ c̅ᵢ̅)̅) is obtained at the output terminal of the voltage comparator as a summation result sᵢ of the i^{th} round addition.

sₙ . . . s₂s₁ and cₙ₊₁ are an addition result of the desired n-bit numbers aₙ . . . a₂a₁ and bₙ . . . b₂b₁.

Herein, i=1, 2, . . . , n, 0<V₁−Vₛₑₜ, V₁/2<V_{Ref1}<2V₁/3, 0<V₂<Vₛₑₜ, and V₂/3<V_{Ref2}<V₂/2. Vₛₑₜ is a threshold for each memristor to transition from a high resistance state to a low resistance state. When a voltage at the first input terminal of the voltage comparator is greater than a voltage at the second input terminal, the output terminal outputs a first level, and the first level is used as a result “1” of the majority gate logic operation; otherwise, the output terminal outputs a second level, and the second level is used as a result “0” of the majority gate logic operation.

Further preferably, corresponding logic values are written by setting the high and low resistance states of the memristors. The high resistance state of the memristors corresponds to the logic value “0”, and the low resistance state corresponds to the logic value “1”.

In the fourth aspect, the disclosure provides an addition operation apparatus including an adder circuit and a controller.

The adder circuit includes a voltage comparator, a resistor, and five memristors. Negative terminals of the five memristors are all connected to one end of the resistor, and the other end of the resistor is grounded. A first input terminal of the voltage comparator is connected to a common node of the five memristors and the resistor, and a resistance value of the resistor is a low resistance state resistance value of the memristors.

The controller is configured to execute the control method provided by the third aspect of the disclosure.

In the fifth aspect, the disclosure provides a control system including a memory and a processor. The memory stores a computer program, and the processor executes the control method provided by the first aspect or the third aspect of the disclosure when executing the computer program.

In the sixth aspect, the disclosure further provides a computer-readable storage medium, and the computer-readable storage medium stores a computer program. When the computer program is executed by a processor, an apparatus where the computer-readable storage medium is located is controlled to execute the control method provided by the first aspect or the third aspect of the disclosure.

In the seventh aspect, the disclosure further provides a computer program product including a computer program/instruction. When the computer program/instruction is executed by a processor, the control method provided by the first aspect or the third aspect of the disclosure is implemented.

In general, the above technical solutions provided by the disclosure have the following beneficial effects:
1. In the control method of the non-volatile majority gate circuit based on memristors and the corresponding majority gate operation apparatus provided by the disclosure, the majority gate circuit includes three memristors, one resistor, and one voltage comparator. The three memristors correspond to input logic values a, b, and c to be subjected to a majority gate logic operation, and a result of the majority gate logic operation is determined by the voltage comparator according to the comparison result between the common node voltage and the reference voltage. By changing the voltage at the positive terminals of the memristors, both the conventional majority gate logic M(a, b, c) and the novel majority gate logic M(a, b, c̅) containing inversion logic are implemented. The implementation of the majority gate logic M(a, b, c̅) avoids decomposing it into two independent logic operations of majority gate logic M(a, b, c) and inversion logic, and is achievable through a one-step voltage application method. As such, in implementation processes of different types of majority gate logic, there is no need to increase the number of memristors, the two types of majority gate logic operations can be implemented with fewer devices and faster computation speed, and these two types of majority gate logic are complete. Any Boolean function can be implemented by combining the two types of majority gate logic, and the requirements for multi-functional logic are thereby satisfied. Based on the above, in the disclosure, the demand for multi-functional logic in practical applications is satisfied with higher integration density and faster computation speed.
2. In the control method for a non-volatile majority gate circuit based on memristors and the corresponding majority gate operation apparatus provided by the disclosure, after the logic computation is completed, the states of the three input memristors still retain the written input information values, which is non-destructive to the input information. In addition, it is non-volatile, so a majority gate logic circuit whose input is the resistance value of a memristor and whose operation process is non-destructive is implemented. The circuit has strong data reuse and no additional copying operations are required to save data in practical applications.
3. The control method for the adder circuit and the corresponding addition operation apparatus provided by the disclosure are implemented based on the implementation concept of majority gate logic operation provided in the first aspect of the disclosure. By combining the two types of majority gate logic M(a, b, c) and M(a, b, c̅) and respectively adopting the control methods for implementing M(a, b, c) and M(a, b, c̅) provided in the first aspect of the disclosure for corresponding control, addition operations can be implemented with fewer devices and faster computation speed.

### BRIEF DESCRIPTION OF THE DRAWINGS

FIG. 1 is a schematic diagram of a majority gate circuit provided by an embodiment of the disclosure.

FIG. 2 is a schematic diagram of controlling majority gate logic M(a, b, c) provided by an embodiment of the disclosure.

FIG. 3 is a schematic diagram of a design concept of the majority gate logic M(a, b, c) provided by an embodiment of the disclosure.

FIG. 4 is a schematic diagram of controlling majority gate logic M(a, b, c̅) provided by an embodiment of the disclosure.

FIG. 5 is a schematic diagram of a design concept of the majority gate logic M(a, b, c̅) provided by an embodiment of the disclosure.

FIG. 6 is a schematic diagram of an adder circuit provided by the disclosure.

FIG. 7 is a schematic diagram of gate-level representation for implementing an addition operation based on majority gate logic provided by the disclosure.

FIG. 8 is a test result of a 1-bit addition operation circuit based on two types of majority gate logic provided by the disclosure.

### DESCRIPTION OF THE EMBODIMENTS

In order to make the objectives, technical solutions, and advantages of the disclosure clearer and more comprehensible, the disclosure is further described in detail with reference to the drawings and embodiments. It should be understood that the specific embodiments described herein serve to explain the disclosure merely and are not used to limit the disclosure. In addition, the technical features involved in the various embodiments of the disclosure described below can be combined with each other as long as the technical features do not conflict with each other.

To achieve the above, in the first aspect, the disclosure provides a control method for a non-volatile majority gate circuit based on memristors.

The majority gate circuit includes a voltage comparator, a resistor, and three identical memristors. Negative terminals of the three memristors are all connected to one end of the resistor, and the other end of the resistor is grounded. A first input terminal of the voltage comparator is connected to a common node of the three memristors and the resistor, and a resistance value of the resistor is a low resistance state resistance value of the memristors.

The control method includes the following steps.

Logic values a, b, and c to be subjected to a majority gate logic operation are correspondingly written into the three memristors. A voltage Vₐ is applied to a positive terminal of the memristor into which the logic value a is written, a voltage V_{b} is applied to a positive terminal of the memristor into which the logic value b is written, and a voltage V_{c} is applied to a positive terminal of the memristor into which the logic value c is written. A reference voltage V_{Ref} is connected to a second input terminal of the voltage comparator. A result of the majority gate logic operation is obtained at an output terminal of the voltage comparator.

When a majority gate logic operation M(a, b, c)=a·b+a·c+b·c is performed on the logic values a, b, and c, Vₐ=V_{b}=V_{c}=V₁, V_{Ref}=V_{Ref1}, 0<V₁<Vₛₑₜ, and V₁/2<V_{Ref1}<2V₁/3.

When a majority gate logic operation M(a, b, c̅)=a·b+a·c̅+b·c̅ is performed on the logic values a, b, and c, Vₐ=V_{b}=V₂, V_{c}=0, V_{Ref}=V_{Ref2}, 0<V₂<Vₛₑₜ, and V₂/3<V_{Ref2}<V₂/2.

Vₛₑₜ is a threshold for each memristor to transition from a high resistance state to a low resistance state. When a voltage at the first input terminal of the voltage comparator is greater than a voltage at the second input terminal, the output terminal outputs a first level, and the first level is used as a result “1” of the majority gate logic operation, otherwise, the output terminal outputs a second level, and the second level is used as a result “0” of the majority gate logic operation.

It may be understood that a correspondence relationship between the output level of the voltage comparator and the logic value may be flexibly set. For instance, with the first input terminal as a positive terminal, the second input terminal as a negative terminal, the first level as a high level, the second level as a low level, the high level is used as the result “1” of the majority gate logic operation, and the low level is used as the result “0” of the majority gate logic operation. It may also be that the first input terminal is a negative terminal, the second input terminal is a positive terminal, the first level is a low level, the second level is a high level, the low level is used as the result “1” of the majority gate logic operation, and the high level is used as the result “0” of the majority gate logic operation.

In the second aspect, the disclosure provides a majority gate operation apparatus including a majority gate circuit and a controller.

The majority gate circuit includes a voltage comparator, a resistor, and three identical memristors. Negative terminals of the three memristors are all connected to one end of the resistor, and the other end of the resistor is grounded. A first input terminal of the voltage comparator is connected to a common node of the three memristors and the resistor, and a resistance value of the resistor is a low resistance state resistance value of the memristors.

The controller is configured to execute the control method provided by the first aspect of the disclosure.

Related technical solutions are the same as the control method provided by the first aspect of the disclosure, so description thereof is not repeated herein.

In order to further illustrate the control method of the non-volatile majority gate circuit based on memristors and the corresponding majority gate operation apparatus provided by the disclosure, detailed description is given in the following paragraphs in combination with a specific embodiment.

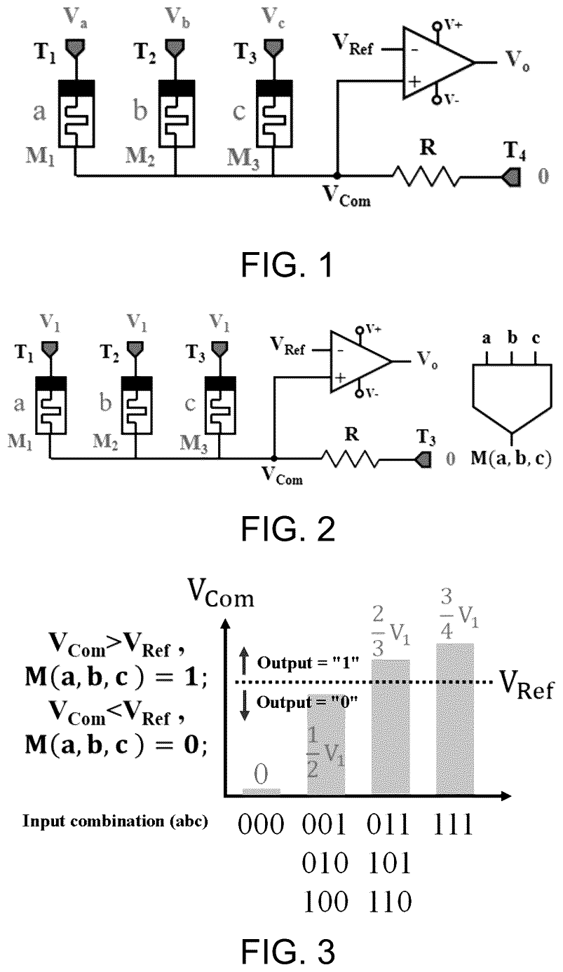

As shown in FIG. 1, this embodiment provides a majority gate circuit including three memristors M₁, M₂, and M₃, a fixed-value resistor, and a voltage comparator. Positive terminals of the memristors M₁, M₂, and M₃ are controlled through control terminals T₁, T₂, and T₃. One end of the fixed-value resistor is controlled through a control terminal T₄, and another end of the fixed-value resistor is connected to negative terminals of the memristors M₁, M₂, and M₃. A voltage of this common node is represented by V_{Com}, and control voltages of the other four control terminals T₁, T₂, T₃, and T₄ are V_{T1}, V_{T2}, V_{T3}, and V_{T4} respectively. A positive terminal of the voltage comparator is connected to the common node of the memristors and the series resistor, a negative terminal is connected to a reference voltage V_{Ref}, and an output terminal voltage is Vₒ.

Each memristor includes two resistance states, namely high resistance state (HRS) and low resistance state (LRS), and the memristor may transition between the two resistance states by applying a terminal voltage of a specific direction and magnitude. By applying a forward voltage greater than Vₛₑₜ, the memristor may be set from the high resistance state to the low resistance state. Conversely, by applying a reverse voltage less than Vᵣₑₛₑₜ, the memristor may transition from the low resistance state to the high resistance state. Vₛₑₜ is a threshold for the memristor to transition from the high resistance state to the low resistance state, and Vᵣₑₛₑₜ is a threshold for the memristor to transition from the low resistance state to the high resistance state.

The high and low configuration resistance values of the memristor are R_{H} and R_{L} respectively, R_{H}<<R_{L}. Preferably, in this embodiment, the resistance value of the resistor is equal to the low resistance value of the memristor. In the case where the memristor high resistance R_{H}=100KΩ and the low resistance R_{L}=1KΩ, the resistor R=1KΩ.

Three input variables a, b, and c of the majority gate logic are respectively mapped to the resistance states of the memristors M₁, M₂, and M₃, where, the high resistance state of each memristor corresponds to a logic value “0”, and the low resistance state of the memristor corresponds to a logic value “1”. The logic output is the voltage value of the output terminal of the comparator. Outputting Vₒ=V+ indicates that the output is a high level, corresponding to the logic result “1”, and outputting Vₒ=V− indicates that the output is a low level, corresponding to the logic result “0”.

Further, based on the above logic circuit, only by changing the control voltage applied to the control terminals T₁, T₂, T₃, and T₄, two types of the majority gate logic M(a, b, c) and M(a, b, c̅) may be implemented. The specific implementation steps are provided as follows.

### (1) Implementation of Majority Gate Logic M(a, b, c)

As shown in FIG. 2, by applying the voltages V₁, V₁, V₁, and 0 to the control terminals T₁, T₂, T₃ and T₄ respectively, V_{Ref}=V_{Ref1}, and the result of the logic operation is obtained through the output terminal of the voltage comparator. The principle of logic implementation lies in that when at least two memristors among the input memristors M₁, M₂, and M₃ are in a low resistance state, the voltage V_{Com} at the common node is greater than the reference voltage V_{Ref1} of the comparator, so that a high level “1” is output. Conversely, when at most one memristor among the input memristors M₁, M₂, and M₃ is in a low resistance state, the voltage V_{Com} at the common node is less than the reference voltage V_{Ref1} of the comparator, so that a low level “0” is output. Specifically, to implement the majority gate logic M(a, b, c), the terminal voltage V₁ and the reference voltage V_{Ref} of the voltage comparator need to satisfy the following constraint conditions: 0<V₁<Vₛₑₜ and V₁/2<V_{Ref1}<2V₁/3, and the design concept of which is shown in FIG. 3.

### (2) Implementation of Majority Gate Logic M(a, b, c̅)

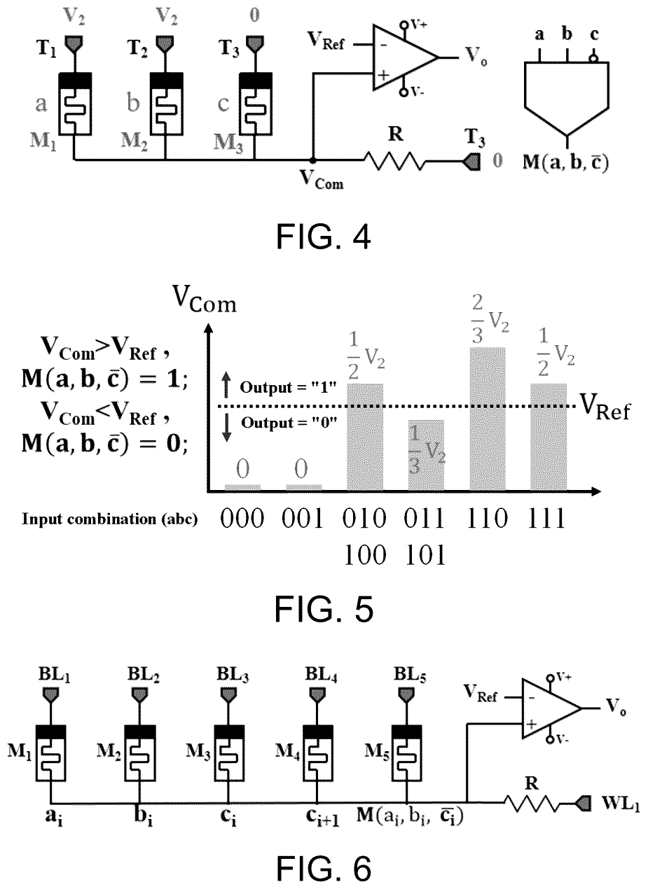

As shown in FIG. 4, by applying the voltages V₂, V₂, 0, and 0 to the control terminals T₁ T₂, T₃ and T₄ respectively, V_{Ref}=V_{Ref2}, and the result of the logic operation is obtained through the output terminal of the voltage comparator. The principle of logic implementation lies in that when the input memristors M₁ and M₂ are at a low resistance “1”, the voltage V_{Com} of the common node can be pulled up. When the voltage V_{Com} of the common node is greater than the reference voltage V_{Ref2} of the comparator, a high level “1” is output. While when the input memristor M₃ is at a low resistance, the voltage V_{Com} of the common node can be pulled down. The voltage V_{Com} of the common node is less than the reference voltage V_{Ref2} of the comparator, so that a low level “0” is output. Specifically, to implement majority gate logic M(a, b, c̅), the terminal voltage V2 and the reference voltage V_{Ref2} of the comparator need to satisfy the following constraint conditions: 0<V₂<Vₛₑₜ and V₂/3<V_{Ref2}<V₂/2, and the design concept of which is shown in FIG. 5.

The disclosure provides an implementation method for reconfigurable majority gate logic based on memristors, in which two types of majority gate logic M(a, b, c) and M(a, b, c̅) may be implemented by only applying different terminal voltages, so that the efficiency of arithmetic operations is improved. Meanwhile, the proposed two types of majority gate logic are complete. Any Boolean function may be implemented by combining the two types of logic, such as for logic a·c, it may be implemented by setting b=0 in logic M(a, b, c), for logic a+c, it may be implemented by setting b=0 in logic M(a, b, c), for logic a·c̅, it may be implemented by setting b=0 in logic M(a, b, c̅), for logic a+c̅, it may be implemented by setting b=1 in logic M(a, b, c̅), and for more complex logic expressions, they may be implemented by iterating the above logic.

Considering that adders are the most fundamental arithmetic units in digital circuit design, their performance directly affects the efficiency and power consumption of data processing. A conventional CMOS adder relies on a full adder structure, whose implementation process requires multiple logic gates in cascade, especially in carry calculation, the delay shows a linear accumulation trend as the number of bits increases. This cascaded logic not only leads to large hardware resource consumption, but also exhibits obvious performance bottlenecks in high-bit adder expansion. The memristor-based adder design provides a new optimization approach. For instance, implementing Boolean calculation of carry output and sum output through majority gate logic may significantly reduce logic levels and delay. However, conventional majority gate and inversion logic are two independent logic operations, which require iterating more computational steps when implementing full adder functions, so the computational speed and area efficiency still need to be further improved. Therefore, the disclosure focuses on adders as an example, so as to specifically illustrate the application of the two majority gate logic implementation methods provided by the disclosure in the adder operation implementation process, specifically as follows:

In the third aspect, the disclosure provides a control method for an adder circuit, used to implement an addition operation of n-bit numbers aₙ . . . a₂a₁ and bₙ . . . b₂b₁. As shown in FIG. 6, the adder circuit includes: a voltage comparator, a resistor, and five memristors. Negative terminals of the five memristors are all connected to one end of the resistor, and the other end of the resistor is grounded. A first input terminal of the voltage comparator is connected to a common node of the five memristors and the resistor, a resistance value of the resistor is a low resistance state resistance value of the memristors, and n≥1.

The control method includes the following. n rounds of addition sub-processes are executed, where in an i^{th} round addition sub-process, the following operations are executed.

Three memristors are selected and denoted as a first memristor, a second memristor, and a third memristor. A logic value aᵢ is written into the first memristor, a logic value bᵢ is written into the second memristor, and a carry cᵢ of the i^{th} round of addition is written into the third memristor. Logic “1” represents that a memristor resistance state is set to low resistance, and logic “0” represents that the memristor resistance state to is set to high resistance. When i=1, the carry c₁ is input by a user, which may be logic “1” or logic “0”.

A voltage V₁is applied to positive terminals of the first memristor, the second memristor, and the third memristor. A reference voltage V_{Ref1} is connected to a second input terminal of the voltage comparator, and a result of a majority gate logic operation M(aᵢ, bᵢ, cᵢ)=aᵢ·bᵢ+aᵢ·cᵢ +bᵢ·cᵢ is obtained at an output terminal of the voltage comparator as a carry cᵢ+1 of an (i+1)^{th} round addition. In this process, the first memristor, the second memristor, the third memristor, the resistor, and the voltage comparator constitute the majority gate circuit in the first aspect of the disclosure. Through the control method provided by the first aspect of the disclosure, the majority gate logic operation M(aᵢ, bᵢ, cᵢ)=aᵢ·bᵢ+aᵢ·cᵢ+bᵢ·cᵢ is implemented.

A voltage V₂ is applied to the positive terminals of the first memristor and the second memristor, and a voltage with an amplitude of 0 is applied to the positive terminal of the third memristor. A reference voltage V_{Ref2} is connected to the second input terminal of the voltage comparator, and a result of a majority gate logic operation M(aᵢ, bᵢ, c̅ᵢ)=aᵢ·bᵢ+aᵢ·c̅ᵢ+bᵢ·c̅ᵢ is obtained at the output terminal of the voltage comparator, which is denoted as sᵢ. In this process, the first memristor, the second memristor, the third memristor, the resistor, and the voltage comparator constitute the majority gate circuit in the first aspect of the disclosure. Through the control method provided by the first aspect of the disclosure, the majority gate logic operation M(a, b, c̅)=a·b+a·c̅+b·c̅ is implemented.

The remaining two unset memristors are denoted as a fourth memristor and a fifth memristor. M(aᵢ, bᵢ, cᵢ) is written into the fourth memristor, and M(aᵢ, bᵢ, c̅ᵢ) is written into the fifth memristor.

The voltage V₂ is applied to positive terminals of the third memristor and the fifth memristor, and a voltage with an amplitude of 0 is applied to a positive terminal of the fourth memristor. The reference voltage V_{Ref2} is connected to the second input terminal of the voltage comparator, and a result of a majority gate logic operation M(cᵢ, M(aᵢ, bᵢ, c̅ᵢ), M̅(̅a̅ᵢ̅,̅ b̅ᵢ̅,̅ c̅ᵢ̅)̅) is obtained at the output terminal of the voltage comparator as a summation result sᵢ of the i^{th} round addition. In this process, the third memristor, the fifth memristor, the fourth memristor, the resistor, and the voltage comparator constitute the majority gate circuit in the first aspect of the disclosure. Through the control method provided by the first aspect of the disclosure, the majority gate logic operation M(cᵢ, M(aᵢ, bᵢ, cᵢ), M̅(̅a̅ᵢ̅,̅ b̅ᵢ̅,̅ c̅ᵢ̅)̅)is implemented.

After n rounds of addition sub-processes, sₙ . . . s₂s₁ and cₙ₊₁ are an addition result of the desired n-bit numbers aₙ . . . a₂a₁ and bₙ . . . b₂b₁.

Herein, i=1, 2, . . . , n, 0<V₁<Vₛₑₜ, V₁/2<V_{Ref1}<2V₁/3, 0<V₂<Vₛₑₜ, and V₂/3<V_{Ref2}<V₂/2 . Vₛₑₜ is a threshold for each memristor to transition from a high resistance state to a low resistance state. When a voltage at the first input terminal of the voltage comparator is greater than a voltage at the second input terminal, the output terminal outputs a first level, and the first level is used as a result “1” of the majority gate logic operation, otherwise, the output terminal outputs a second level, and the second level is used as a result “0” of the majority gate logic operation.

It may be understood that a correspondence relationship between the output level of the voltage comparator and the logic value may be flexibly set. For instance, with the first input terminal as a positive terminal, the second input terminal as a negative terminal, the first level as a high level, the second level as a low level, the high level is used as the result “1” of the majority gate logic operation, and the low level is used as the result “0” of the majority gate logic operation. It may also be that the first input terminal is a negative terminal, the second input terminal is a positive terminal, the first level is a low level, the second level is a high level, the low level is used as the result “1” of the majority gate logic operation, and the high level is used as the result “0” of the majority gate logic operation.

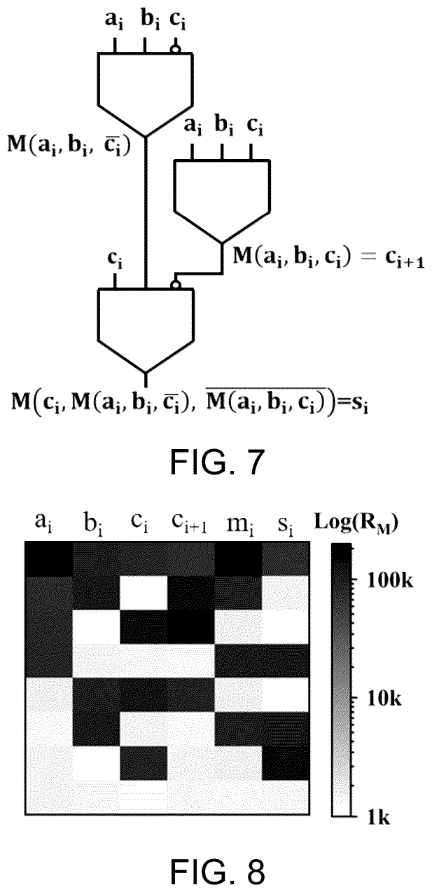

A schematic diagram of gate-level representation for implementing an addition operation based on majority gate logic is shown in FIG. 7.

It should be noted that the execution order of the majority gate logic operation M(aᵢ, bᵢ, cᵢ=aᵢ·bᵢ+aᵢ·cᵢ+bᵢ·cᵢ and the majority gate logic operation M(a, b, c̅)=a·b+a·c̅+b·c̅ is not limited.

Further, a 1-bit addition operation circuit (n=1) based on two types of majority gate logic is used as an example for illustration. Specifically, the memristor has high resistance R_{H}=100KΩ, low resistance R_{L}=1KΩ, and resistance R=1KΩ. The adder function is verified, and experimental results as shown in FIG. 8 is obtained (where RM represents the resistance value of the memristor). It may be seen from the figure that the one-bit full adder provided by the disclosure functions correctly, and computational accuracy in the disclosure is high.

In the fourth aspect, the disclosure provides an addition operation apparatus including an adder circuit and a controller.

The adder circuit includes a voltage comparator, a resistor, and five memristors. Negative terminals of the five memristors are all connected to one end of the resistor, and the other end of the resistor is grounded. A first input terminal of the voltage comparator is connected to a common node of the five memristors and the resistor, and a resistance value of the resistor is a low resistance state resistance value of the memristors.

The controller is configured to execute the control method provided by the third aspect of the disclosure.

Preferably, in an optional implementation, the resistance value of the resistor is the low resistance state resistance value of the memristors.

Related technical solutions are the same as the control method provided by the third aspect of the disclosure, so description thereof is not repeated herein.

In the fifth aspect, the disclosure provides a control system including a memory and a processor. The memory stores a computer program, and the processor executes the control method provided by the first aspect or the third aspect of the disclosure when executing the computer program.

Related technical solutions are the same as the control method provided by the first aspect or the third aspect of the disclosure, so description thereof is not repeated herein.

In the sixth aspect, the disclosure further provides a computer-readable storage medium, and the computer-readable storage medium stores a computer program. When the computer program is executed by a processor, an apparatus where the computer-readable storage medium is located is controlled to execute the control method provided by the first aspect or the third aspect of the disclosure.

Related technical solutions are the same as the control method provided by the first aspect or the third aspect of the disclosure, so description thereof is not repeated herein.

In the seventh aspect, the disclosure further provides a computer program product including a computer program/instruction. When the computer program/instruction is executed by a processor, the control method provided by the first aspect or the third aspect of the disclosure is implemented.

In view of the foregoing, in the disclosure, by designing a reconfigurable majority gate logic circuit based on memristors and its adder implementation scheme, the problems of singularity found in memristor majority gate logic and high delay and large hardware overhead of addition arithmetic functions in the related art are solved. The two proposed majority gates include both the conventional three-input majority gate logic M(a, b, c)=a·b+a·c+b·c, and the novel majority gate logic containing inversion logic M(a, b, c̅)=a·b+a·c̅+b·c̅. By setting a=“0” and b=“1” in the majority gate logic M(a, b, c̅), M(0, 1, c̅)=c̅ is obtained, and inversion logic is thus implemented. The proposed two types of reconfigurable logic may implement MIG logic, and since MIG logic is complete, the proposed reconfigurable logic is complete. Any Boolean function may be implemented through iterating the proposed two types of majority gate logics. By combining the in-memory computing characteristics of memristors, in the disclosure, the performance of logic operations and arithmetic functions such as adders may be effectively improved, hardware resource consumption and delay may be significantly reduced, and a new technical path for efficiently implementing in-memory computing is provided.

A person having ordinary skill in the art should be able to easily understand that the above description is only preferred embodiments of the disclosure and is not intended to limit the disclosure. Any modifications, equivalent replacements, and modifications made without departing from the spirit and principles of the disclosure should fall within the protection scope of the disclosure.

What is claimed is:

1. A control method for a non-volatile majority gate circuit based on memristors, wherein the majority gate circuit comprises a voltage comparator, a resistor, and three identical memristors;
negative terminals of the three memristors are all connected to one end of the resistor, the other end of the resistor is grounded, a first input terminal of the voltage comparator is connected to a common node of the three memristors and the resistor, and a resistance value of the resistor is a low resistance state resistance value of the memristors,
the control method comprises:
correspondingly writing logic values a, b, and c to be subjected to a majority gate logic operation into the three memristors, applying a voltage Vₐ to a positive terminal of the memristor into which the logic value a is written, applying a voltage V_{b} to a positive terminal of the memristor into which the logic value b is written, applying a voltage V_{c} to a positive terminal of the memristor into which the logic value c is written, connecting a reference voltage V_{Ref} to a second input terminal of the voltage comparator, and obtaining a result of the majority gate logic operation at an output terminal of the voltage comparator,
wherein when a majority gate logic operation M(a, b, c)=a·b+a·c+b·c is performed on the logic values a, b, and c, Vₐ =V_{b} =V_{c} =V₁, V_{Ref}=V_{Ref1}, 0<V₁<Vₛₑₜ, and V₁/2<V_{Ref1}<2V₁/3,
when a majority gate logic operation M(a, b, c̅)=a·b+a·c̅+b·c̅ is performed on the logic values a, b, and c, Vₐ=V_{b}=V₂, V_{c}=0, V_{Ref}=V_{Ref2}, 0<V₂<Vₛₑₜ, and V₂/3<V_{Ref2}<V₂/_{Ref2}
Vₛₑₜ is a threshold for each memristor to transition from a high resistance state to a low resistance state, when a voltage at the first input terminal of the voltage comparator is greater than a voltage at the second input terminal, the output terminal outputs a first level, and the first level is used as a result “1” of the majority gate logic operation; otherwise, the output terminal outputs a second level, and the second level is used as a result “0” of the majority gate logic operation.

2. The control method according to claim 1, wherein corresponding logic values are written by setting the high and low resistance states of the memristors, wherein the high resistance state of the memristors corresponds to the logic value “0”, and the low resistance state corresponds to the logic value “1”.

3. A majority gate operation apparatus, comprising a majority gate circuit and a controller,
the majority gate circuit comprises a voltage comparator, a resistor, and three identical memristors, negative terminals of the three memristors are all connected to one end of the resistor, the other end of the resistor is grounded, a first input terminal of the voltage comparator is connected to a common node of the three memristors and the resistor, and a resistance value of the resistor is a low resistance state resistance value of the memristors,
the controller is configured to execute the control method according to claim 1.

4. A control method of an adder circuit, for implementing an addition operation of n-bit numbers aₙ . . . a₂a₁ and bₙ . . . b₂b₁, wherein the adder circuit comprises a voltage comparator, a resistor, and five memristors, negative terminals of the five memristors are all connected to one end of the resistor, the other end of the resistor is grounded, a first input terminal of the voltage comparator is connected to a common node of the five memristors and the resistor, a resistance value of the resistor is a low resistance state resistance value of the memristors, and n≥1,
the control method comprises: executing n rounds of addition sub-processes; wherein in an i^{th} round addition sub-process, the following operations are executed:
selecting three memristors denoted as a first memristor, a second memristor, and a third memristor, writing a logic value aᵢ into the first memristor, writing a logic value bᵢ into the second memristor, and writing a carry cᵢ of the i^{th} round addition into the third memristor;
applying a voltage V₁ to positive terminals of the first memristor, the second memristor, and the third memristor, connecting a reference voltage V_{Ref1} to a second input terminal of the voltage comparator, and obtaining a result of a majority gate logic operation M(aᵢ, bᵢ, cᵢ) =aᵢ·bᵢ +aᵢ·cᵢ +bᵢ·cᵢ at an output terminal of the voltage comparator as a carry cᵢ₊₁ of an (i+1)^{th} round addition;
applying a voltage V₂ to the positive terminals of the first memristor and the second memristor, applying a voltage with an amplitude of 0 to the positive terminal of the third memristor, connecting a reference voltage V_{Ref2} to the second input terminal of the voltage comparator, and obtaining a result of a majority gate logic operation M(aᵢ, bᵢ, cᵢ)=aᵢ·bᵢ+aᵢ·cᵢ+bᵢ·cᵢ at the output terminal of the voltage comparator;
denoting the remaining two unset memristors as a fourth memristor and a fifth memristor, writing M(aᵢ, bᵢ, cᵢ) into the fourth memristor, and writing M(aᵢ, bᵢ, cᵢ) into the fifth memristor; and
applying the voltage V₂ to positive terminals of the third memristor and the fifth memristor, applying a voltage with an amplitude of 0 to a positive terminal of the fourth memristor, connecting the reference voltage V_{Ref2} to the second input terminal of the voltage comparator, and obtaining a result of a majority gate logic operation M(cᵢ, M(aᵢ, bᵢ, cᵢ), M(aᵢ, bᵢ, cᵢ)) at the output terminal of the voltage comparator as a summation result sᵢ of the i^{th} round addition,
wherein sₙ . . . s₂s₁ and cₙ₊₁ are an addition result of the desired n-bit numbers aₙ . . . a₂a₁ and bₙ . . . b₂b₁,
wherein i=1, 2, . . . , n, 0<V₁<Vₛₑₜ, V₁/2<V_{Ref1}<2V₁/3, 0<V₂<Vₛₑₜ, and V₂/3<V_{Ref2}<V₂/2, Vₛₑₜ is a threshold for each memristor to transition from a high resistance state to a low resistance state, when a voltage at the first input terminal of the voltage comparator is greater than a voltage at the second input terminal, the output terminal outputs a first level, and the first level is used as a result “1” of the majority gate logic operation; otherwise, the output terminal outputs a second level, and the second level is used as a result “0” of the majority gate logic operation.

5. The control method according to claim 4, wherein corresponding logic values are written by setting the high and low resistance states of the memristors, wherein the high resistance state of the memristors corresponds to the logic value “0”, and the low resistance state corresponds to the logic value “1”.

6. An addition operation apparatus, comprising an adder circuit and a controller,
wherein the adder circuit comprises: a voltage comparator, a resistor, and five memristors, negative terminals of the five memristors are all connected to one end of the resistor, the other end of the resistor is grounded, a first input terminal of the voltage comparator is connected to a common node of the five memristors and the resistor, and a resistance value of the resistor is a low resistance state resistance value of the memristors,
the controller is configured to execute the control method according to claim 4.

7. A control system, comprising a memory and a processor, the memory stores a computer program, and the processor executes the control method according to claim 1 when executing the computer program.

8. A computer-readable storage medium, comprising a stored computer program, wherein when the computer program is executed by a processor, an apparatus where the computer-readable storage medium is located is controlled to execute the control method according to claim 1.

9. A computer program product, comprising a computer program/instruction, wherein when the computer program/instruction is executed by a processor, the control method according to claim 1 is implemented.
